(19) United States
(12) Patent Application Publication
(10) Pub. No.: US 2018/0052395 A1
(43) Pub. Date: Feb. 22, 2018

(54) EXPOSURE METHOD, SUBSTRATE AND EXPOSURE APPARATUS

(71) Applicants: BOE TECHNOLOGY GROUP CO., LTD., Beijing (CN); BEIJING BOE DISPLAY TECHNOLOGY CO., LTD., Beijing (CN)

(72) Inventors: Xiao Guang Li, Beijing (CN); Yu Xiao, Beijing (CN); Chao Xue, Beijing (CN); Dong Wang, Beijing (CN)

(21) Appl. No.: 15/658,372

(22) Filed: Jul. 24, 2017

(30) Foreign Application Priority Data
Aug. 19, 2016 (CN) 201610696721.X

(51) Int. Cl. G03F 7/213; G03F 7/00; G03F 7/20; G03F 7/039

(52) U.S. Cl. CPC G03F 7/213; G03F 7/0007; G02B 5/20; G03F 7/039; G03F 7/2022

(57) ABSTRACT

An exposure method, a substrate and an exposure apparatus are disclosed. In one embodiment, an exposure method includes: forming a mask combination from at least two masks; and exposing, by using the mask combination, a film layer to be exposed on a base substrate, until a complete exposed pattern is formed on the film layer to be exposed.

### CROSS-REFERENCE TO RELATED APPLICATION

This application claims priority to Chinese Patent Application No. 201610696721.X filed on Aug. 19, 2016 in the State Intellectual Property Office of China, the disclosures of which are hereby incorporated by reference in their entirety.

### TECHNICAL FIELD

The present disclosure relates to the technical field of photolithography, and particularly, to an exposure method, a substrate and an exposure apparatus.

### BACKGROUND

Presently, in conventional course of manufacturing a substrate, an exposure machine is adopted in its exposure process. A pattern to be formed on a film layer to be exposed of a base substrate is the same as a pattern of a mask. All the patterns are formed after exposure using the masks. Since an exposure is performed on one side of a base substrate (namely unilateral exposure), one mask is only used for one product. Accordingly, the masks for different products are not reused. While, a cost of the masks accounts for the most proportion of the manufacturing cost of the substrate, accordingly the manufacturing cost is greatly high.

Thus it can be seen, the masks used in conventional course of manufacturing a substrate has relatively high cost. It is a problem to be solved urgently for those skilled in the art how to simplify manufacturing of patterns of the film layers and reduce manufacturing cost of the patterns of the film layers.

### SUMMARY

According to an aspect of embodiments of the present disclosure, an exposure method is provided, comprising:

forming a mask combination from at least two masks; and

exposing, by using the mask combination, a film layer to be exposed on a base substrate, until a complete exposed pattern is formed on the film layer to be exposed.

In some embodiments, the step of exposing, by using the mask combination, the film layer to be exposed on the base substrate comprises: exposing, by using a first mask of the mask combination, a film layer to be exposed corresponding to a first region of the base substrate, while exposing, by using a second mask of the mask combination, the film layer to be exposed corresponding to a second region of the base substrate.

In some embodiments, orthographic projections of the first mask and the second mask on the base substrate are overlapped at least partially with each other.

In some other embodiments, orthographic projections of the first mask and the second mask on the base substrate are not overlapped with each other.

In some embodiments, the first mask and the second mask are at the same side of the base substrate.

In some other embodiments, the first mask and the second mask are at different sides of the base substrate, respectively.

In some embodiments, at least one exposure light source is provided to be located at the side of the base substrate at which the first mask and the second mask are located.

In some other embodiments, at least two exposure light sources are provided to be located at the different sides of the base substrate, respectively.

In some embodiments, when a material for the film layer to be exposed is positive photoresist material, the exposed pattern is complementary to a pattern obtained after overlapping all the masks of the mask combination with one another.

In some other embodiments, when a material for the film layer to be exposed is negative photoresist material, the exposed pattern is a superimposed pattern obtained after overlapping all the masks of the mask combination with one another.

In some embodiments, the method is for manufacturing a black matrix layer or a color film layer.

According to another aspect of embodiments of the present disclosure, there is provided a substrate manufactured by using the abovementioned exposure method, and the substrate comprises a base substrate and a black matrix layer and/or a color film layer on the base substrate; wherein,

the black matrix layer and/or the color film layer are/is formed by adopting the above exposure method.

According to yet another aspect of embodiments of the present disclosure, there is provided an exposure apparatus for manufacturing the above substrate, and the exposure apparatus comprises: a first exposure machine and a second exposure machine provided to simultaneously perform exposures on the base substrate at different sides of the base substrate, respectively.

According to still another aspect of embodiments of the present disclosure, there is provided an exposure apparatus for manufacturing the above substrate, and the exposure apparatus comprises: at least one exposure machine provided to perform exposures, by using different masks, on the base substrate at the same side of the base substrate.

In some embodiments, when a material for the film layer to be exposed is positive photoresist material, the exposed pattern is complementary to a pattern obtained after overlapping all the masks of the mask combination with one another.

In some other embodiments, when a material for the film layer to be exposed is negative photoresist material, the exposed pattern is a superimposed pattern obtained after overlapping all the masks of the mask combination with one another.

In some embodiments, the exposure apparatus is for manufacturing a black matrix layer or a color film layer.

### BRIEF DESCRIPTION OF THE DRAWINGS

FIG. 1 is a flow diagram of an exposure method according to an embodiment of the disclosure.

FIG. 2A is a schematic view of a configuration in which exposure processes are performed on upper surface and lower surface of a base substrate by using a first mask and a second mask, respectively, according to an embodiment of the disclosure.

FIG. 2B is a schematic view of a pattern obtained after overlapping of the first mask and the second mask shown in FIG. 2A with each other, according to the embodiment of the disclosure.

FIG. 2C is a schematic view of a pattern obtained after performing exposure processes on a film layer to be exposed by using a configuration shown in FIG. 2A, according to the embodiment of the disclosure.

FIG. 3 is a schematic view of a configuration in which orthographic projections of a first mask and a second mask on a base substrate are overlapped partially with each other, according to an embodiment of the disclosure.

FIG. 4 is a schematic view of a configuration in which orthographic projections of a first mask and a second mask on a base substrate are not overlapped with each other, according to another embodiment of the disclosure.

FIG. 5 is a schematic view of a configuration in which a first mask and a second mask are provided at the same side of a base substrate, according to an embodiment of the disclosure.

### DETAILED DESCRIPTION OF THE EMBODIMENTS

In order to provide a more clear understanding of technical solutions of embodiments of the present disclosure, the embodiments of the present disclosure will be further described hereinafter in detail and completely with reference to the attached drawings. Obviously, the embodiments illustrated in these drawings are only some of embodiments of the present disclosure, instead of all of the embodiments of the present disclosure. For those skilled in the art, other embodiments achieved by referring to the following embodiments without involving any inventive steps fall into the scope of the present disclosure.

In the drawings, shapes and thicknesses of the structures/elements do not reflect a real scale, and the only purpose is to schematically show the embodiments of the present disclosure.

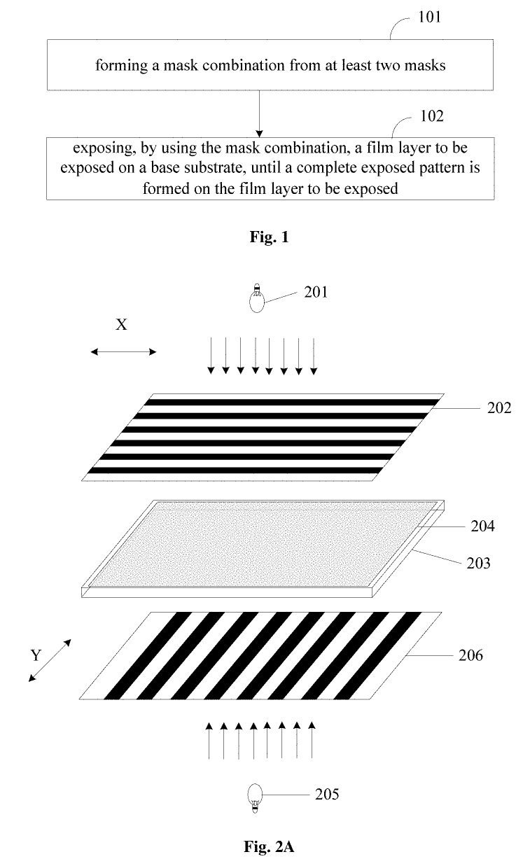

FIG. 1 shows a flow diagram of an exposure method according to an embodiment of the disclosure. Referring to FIG. 1, an exposure method comprises:

a step 101 of forming a mask combination from at least two masks; and

a step 102 of exposing, by using the mask combination, a film layer to be exposed on a base substrate, until a complete exposed pattern is formed on the film layer to be exposed.

In specific implementations, patterns of the masks in the mask combination may be set according to requirements. The patterns may be set to be the same, or may be set to be different according to requirements, as long as a pattern obtained after overlapping all the masks with one another can form the exposed pattern of the film layer to be exposed. According to the present disclosure, since at least two masks are adopted, a pattern (for example, a mixed product) which is difficult to be formed by using one mask can be formed by using the mask combination in one exposure process, thereby simplifying manufacturing of pattern of the film layer. Meanwhile, since each of the masks can be adopted in manufacturing of different patterns, the masks can be reused in other products having different patterns according to requirements, thereby further reducing manufacturing cost of the pattern of the film layer.

Specifically, according to embodiments of the present disclosure, by using the mask combination, exposure of a film layer to be exposed on a base substrate is performed. During an exposure process, by using the mask combination, exposures can be performed on different regions of the base substrate, respectively. Introductions and explanations in detail are taken hereinafter.

In one specific embodiment, the step of exposing, by using the mask combination, the film layer to be exposed on the base substrate may specifically comprise: exposing, by using a first mask of the mask combination, a film layer to be exposed corresponding to a first region of the base substrate, while exposing, by using a second mask of the mask combination, the film layer to be exposed corresponding to a second region of the base substrate.

In specific implementations, quantity of the masks in the mask combination may be set in accordance with requirements, and at least two masks are included. In order to ease the description, a mask combination only including a first mask and a second mask is taken as an example in the embodiments of the present disclosure. In practical, however, it is not limited to the mask combination including only two masks, but a plurality of masks can be included.

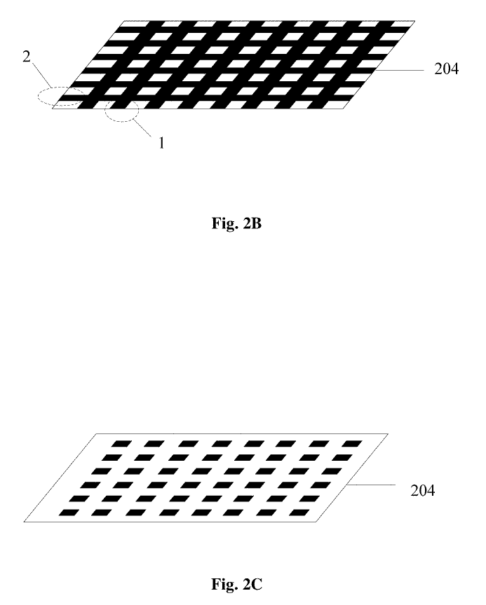

In embodiments where the mask combination only includes two masks, exposures on different regions of the base substrate by respectively using the first mask and the second mask of the mask combination can be performed simultaneously. FIG. 2A is a schematic view of a configuration in which exposure processes are performed on upper surface and lower surface of a base substrate by using a first mask and a second mask, respectively, according to an embodiment of the disclosure. Referring to FIG. 2A, exposure of a film layer 204 to be exposed corresponding to an upper region (namely first region) of the base substrate 203 is performed by using the first mask 202, while exposure of the film layer 204 to be exposed corresponding to a lower region (namely second region) of the base substrate 203 is performed by using a second mask 206. In figures, 201 and 205 indicate two exposure light sources respectively.

In some embodiments, in order to save exposure time and reduce tact time, exposures may be performed on both sides of the base substrate simultaneously. In some other embodiments, according to requirements, exposure may be performed on one side of the base substrate firstly, and then may be performed on the other side of the base substrate. Specific sequence of performing the exposure may be set according to requirements.

In specific implementations, when exposure of the film layer to be exposed 204 on the base substrate is performed by using the first mask 202 and the second mask 206 as shown in FIG. 2A, the film layer to be exposed 204 is located at the upper side of the base substrate 203. Accordingly, when a first exposure light source 201 located at the upper side of the base substrate 203 is adopted to expose the film layer to be exposed 204 by using the first mask 202, a pattern shown as that of the first mask 202 can be formed on the film layer to be exposed 204; and when a second exposure light source 205 located at the lower side of the base substrate 203 is adopted to expose the film layer to be exposed 204 by using the second mask 206, a pattern shown as that of the second mask 206 can be formed on the film layer to be exposed 204. In figures, black region indicates a region in which light is blocked during exposure, and white region indicates a region in which light is not blocked during exposure.

For example, when exposure of the film layer to be exposed 204 on the base substrate is performed by using the first mask 202 and the second mask 206 as shown in FIG. 2A, theoretically, a pattern obtained after overlapping the first mask 202 and the second mask 206 with each other is as shown in FIG. 2B. However, since the base substrate 203 is transparent, light passing through regions 1 is not blocked when the exposure is performed at the upper side of the base substrate by using the first mask 202, and, light passing through regions 2 is not blocked when the exposure is performed at the lower side of the base substrate by using the second mask 206. Accordingly, an actually exposed pattern formed on the film layer to be exposed 204 is shown in FIG. 2C.

Moreover, a complete exposed pattern is formed on the film layer to be exposed after performing exposure of the film layer to be exposed on the base substrate by using the configuration as shown in FIG. 2A. When different photoresist materials are selected, a relationship between the exposed pattern and a pattern obtained after overlapping all the masks of the mask combination with one another varies. In some embodiments, when a material for the film layer to be exposed is positive photoresist material, the exposed pattern is complementary to a pattern obtained after overlapping all the masks of the mask combination with one another. In some other embodiments, when a material for the film layer to be exposed is negative photoresist material, the exposed pattern is a superimposed pattern obtained after overlapping all the masks of the mask combination with one another. In practical, different types of the photoresist materials are selected in order to manufacture different film layers to be exposed.

In specific implementations, the exposure method according to embodiments of the present disclosure can be for manufacturing a black matrix layer or a color film layer. Since shape of the black matrix layer or the color film layer on a display panel varies, different types of the photoresist materials for the film layer to be exposed should be selected according to shape of a film layer to be manufactured. For example, negative photoresist material should be selected if a black matrix of “strip-shaped” structure is required to be manufactured; and positive photoresist material should be selected if a color film of “island-shaped” structure is required to be manufactured.

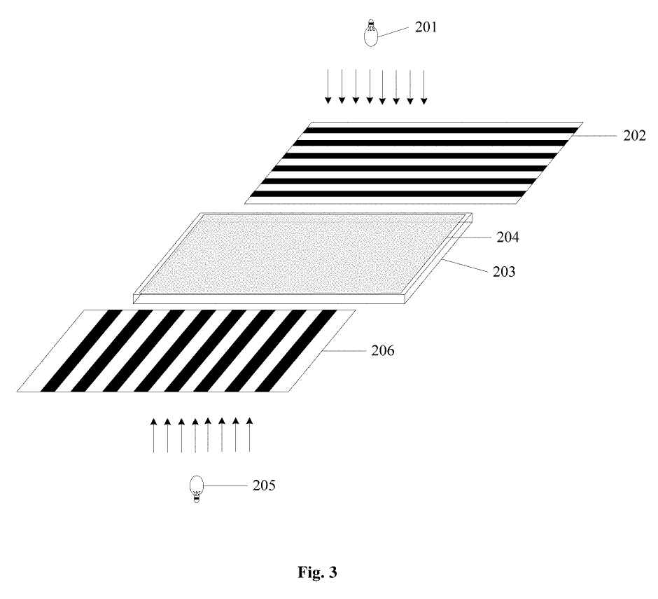

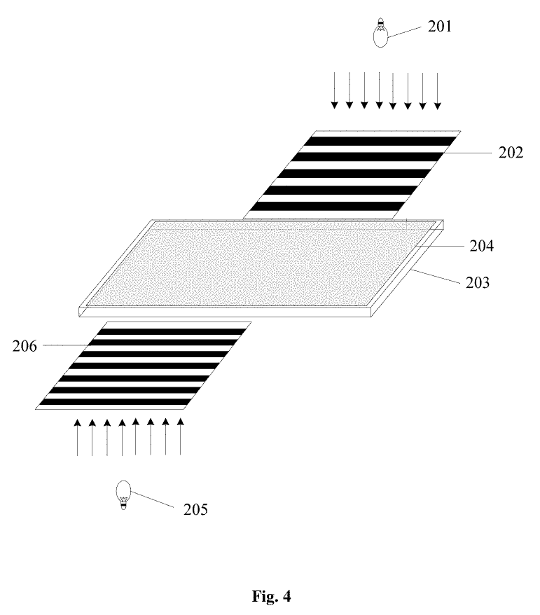

In specific implementations, two masks may be adopted as the mask combination to form a new mask pattern. In exposure process of the film layer to be exposed, the two different masks may be completely overlapped in position with each other, or may be partially overlapped in position with each other. In some embodiments, as shown in FIG. 3, orthographic projections of the first mask and the second mask on the base substrate are at least overlapped partially with each other. In some other embodiments, as shown in FIG. 4, orthographic projections of the first mask and the second mask on the base substrate are not overlapped with each other. Relationship between the two masks in position may be changed according to pattern of a film layer to be manufactured. This positional relationship is not specifically limited herein.

For example, in the embodiment shown in FIG. 2A, a first exposure light source 201 located above the base substrate 203 is adopted to expose the upper region (namely first region) of the base substrate 203 by using the first mask 202, while a second exposure light source 205 located below the base substrate 203 is adopted to expose the lower region (namely second region) of the base substrate 203 by using the second mask 206. When the exposures are performed at both sides of the base substrate 203 simultaneously, orthographic projections of regions (namely the first and second regions) irradiated by the two exposure light sources on the base substrate are overlapped with each other.

For another example, in the embodiment in which orthographic projections of the first mask and the second mask on the base substrate are overlapped partially with each other, as shown in FIG. 3, the first mask 202 and the second mask 206 are staggered from each other in position, here, orthographic projections of the first region and the second region for exposure on the base substrate are overlapped partially with each other. In the embodiments of the present disclosure, which manner and what amount orthographic projections of the first mask 202 and the second mask 206 on the base substrate are overlapped with each other may be set according to a pattern of the film layer to be manufactured (or a pattern of the film layer to be exposed) and patterns of the first mask and the second mask.

Besides that the above two masks are overlapped at least partially in position with each other, according to requirements, the two masks may be not overlapped with each other, that is, orthographic projections of the first mask and the second mask on the base substrate are not overlapped with each other. FIG. 4 shows an embodiment in which orthographic projections of the first mask and the second mask on the base substrate are not overlapped with each other, according to another embodiment of the disclosure.

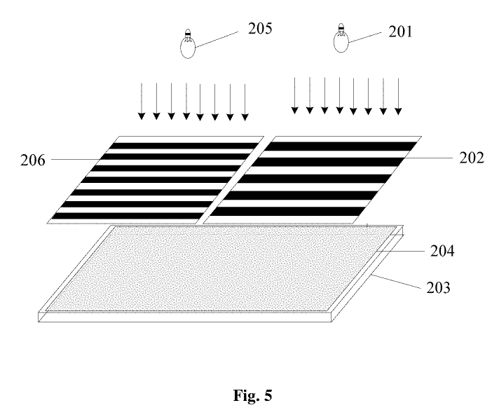

In specific implementations, besides the relationship between the first mask and the second mask in position may be set according to requirements, at which side of the base substrate the first mask and the second mask are specifically provided may also be set according to requirements. In some embodiments, as shown in FIG. 5, the first mask and the second mask are at the same side of the base substrate. In some other embodiments, as shown in FIG. 3 and FIG. 4, the first mask and the second mask are at different sides of the base substrate, respectively.

In order to allow the exposure light source to irradiate the film layer to be exposed directly through the mask so as to reduce exposure time, the first mask and the second mask may be located at the same side of the base substrate. FIG. 5 shows an embodiment in which the first mask and the second mask are provided at the same side of the base substrate, according to an embodiment of the disclosure. In this figure, a first exposure light source 201 is adopted to expose, from right side of a base substrate 203, a right region (namely first region) of the base substrate 203 by using a first mask 202, while a second exposure light source 205 is adopted to expose, from left side of the base substrate 203, a left region (namely second region) of the base substrate 203 by using a second mask 206.

Here, in the embodiment shown in FIG. 5, two masks are adopted to expose two regions of which projections on the base substrate are not overlapped with each other. In fact, in other embodiments, two masks may also be located at the same side of the base substrate when projections of the two masks on the base substrate are overlapped partially with each other. In which side of the base substrate the two masks are specifically provided can also be set according to requirements.

Quantity, locations and positional relationship of the masks can be set according to requirements, correspondingly, quantity and locations of the exposure light sources can also be set according to requirements. In some embodiments in which the first mask and the second mask are at the same side of the base substrate, at least one exposure light source is provided to be located at the side of the base substrate at which the first mask and the second mask are located. In some other embodiments in which the first mask and the second mask are at different sides of the base substrate, respectively, at least two exposure light sources are provided to be located at the different sides of the base substrate, respectively.

In specific implementations, in an embodiment in which the first mask and the second mask are at the same side of the base substrate, at least one exposure light source is provided, and exposures of a film layer to be exposed corresponding to first region and second region are performed respectively by using the first mask and the second mask of the mask combination located at the side where the film layer to be exposed is provided, as shown in FIG. 5, that is, two exposure light sources (namely first exposure light source 201 and second exposure light source 205, or else one exposure light source is provided according to requirements) and two masks (namely first mask 202 and second mask 206) are at the same side of the base substrate, correspondingly, the first region and second region of the base substrate for exposure of the film layer to be exposed are at the same side of the base substrate.

Alternatively, in another embodiment in which the first mask and the second mask are at different side of the base substrate, respectively, a first exposure light source is provided to expose a film layer to be exposed corresponding to a first region of the base substrate by using the first mask of the mask combination, while a second exposure light source is provided to expose a film layer to be exposed corresponding to a second region of the base substrate by using the second mask of the mask combination, as shown in FIG. 2A, FIG. 3 and FIG. 4, that is, according to requirements, two exposure light sources (namely first exposure light source 201 and second exposure light source 205) and two masks (namely first mask 202 and second mask 206) are provided respectively at different sides of the base substrate, correspondingly, first region and second region of the base substrate for exposure of the film layer to be exposed are provided respectively at different sides of the base substrate.

The present disclosure adopts at least two masks, and thus can be applied in manufacturing of a mixed product according to requirements. Meanwhile, since it is difficult and is costly to form two different patterns in one mask, for a product in which different patterns are required to be form on the same film layer to be exposed, the method according to the present disclosure can be applied to form different patterns in two masks respectively, and to expose two regions by using the two masks respectively, such that the object of forming different patterns in the same film layer to be exposed is achieved and the two masks can be reused in other products for forming similar patterns, which effectively reduces manufacturing cost of the product.

Moreover, in order to reduce exposure time, the exposure method according to the embodiments of the present disclosure may be developed to adopt a plurality of exposure light sources and a plurality of corresponding masks. Based on patterns of the masks, patterns formed on the film layer to be exposed may be changed by adjusting distances between the masks and the substrate according to requirements.

Based on the same inventive concept, according to the embodiments of the present disclosure, there also provides a substrate manufactured by using the exposure method according to the embodiments of the present disclosure. The substrate comprises a base substrate and a black matrix layer and/or a color film layer on the base substrate; wherein, the black matrix layer and/or the color film layer are/is formed by adopting the exposure method according to the embodiments of the present disclosure. Principle of manufacturing the substrate is similar to that of the above exposure method according to the embodiments of the present disclosure, accordingly, implementations of the substrate may refer to those of the above exposure method according to the embodiments of the present disclosure and is no longer described for the sake of brevity.

Based on the same inventive concept, according to the embodiments of the present disclosure, there also provides an exposure apparatus for manufacturing the substrate according to the embodiments of the present disclosure. The exposure apparatus comprises: a first exposure machine and a second exposure machine provided to simultaneously perform exposures on the base substrate at different sides of the base substrate, respectively. Working principle of the exposure apparatus is similar to that of the above substrate according to the embodiments of the present disclosure, accordingly, implementations of the exposure apparatus may refer to those of the above substrate according to the embodiments of the present disclosure and is no longer described for the sake of brevity.

Referring to FIG. 2A, a first exposure machine (for example first exposure light source 201) is provided to form a pattern in an X direction by using a first mask at the upper side, while a second exposure machine (for example second exposure light source 205) is provided to form a pattern in a Y direction by using a second mask at the lower side, to form a whole pattern of the base substrate. In other embodiments, one mask of whole pattern is provided at each of the lower side and the upper side, for exposing different regions of the base substrate, as shown in FIG. 4, so as to greatly reduce tact time and improve productivity.

In an example in which a black matrix layer is manufactured, a black matrix frame pattern in an X direction is formed by using a first mask of a first exposure machine, and a black matrix frame pattern in a Y direction is formed by using a second mask of a second exposure machine, and then a complete black matrix frame pattern is formed by exposure implemented by the first exposure machine and the second exposure machine at the upper and the lower sides. Various mask combinations may be achieved by providing several first masks and several second masks, which can theoretically form any black matrix frame patterns. As a result, new products can be manufactured by adoption of existing first masks and second masks for exposure, without providing any new mask, and thus the cost is reduced. Exposure gap and amount of exposure of the first exposure machine and the second exposure machine can be controlled independently in order to improve manufacturing process. For similar reason, pattern of a color film layer can be achieved by this method, which greatly reduces the cost of developing a new product.

Concerning the above, in the exposure method, the substrate and the exposure apparatus according to the embodiment of the present disclosure, a mask combination consisted of at least two masks is adopted to expose a film layer to be exposed, so as to form a complete pattern of the film layer to be exposed. Since the mask combination consisted of at least two masks is adopted in the embodiment of the present disclosure, a pattern which is difficult to be formed by using one mask can be formed by using the mask combination in one exposure process, thereby simplifying manufacturing of pattern of the film layer. Meanwhile, since each of the masks can be formed with a different pattern, the masks can be reused in other products having different patterns according to requirements, thereby further reducing manufacturing cost of the pattern of the film layer.

It will be apparent for those skilled in the art that some changes and modifications on these embodiments may be made without departing from the principles and spirit of the present disclosure. All of changes and modifications made within principles and spirit of the disclosure should be included within the scope of the present disclosure, and the scope of which is defined in the claims and their equivalents.

What is claimed is:

1. An exposure method, comprising:
forming a mask combination from at least two masks; and
exposing, by using the mask combination, a film layer to be exposed on a base substrate, until a complete exposed pattern is formed on the film layer to be exposed.

2. The method of claim 1, wherein the step of exposing, by using the mask combination, the film layer to be exposed on the base substrate comprises:
exposing, by using a first mask of the mask combination, a film layer to be exposed corresponding to a first region of the base substrate, while exposing, by using a second mask of the mask combination, the film layer to be exposed corresponding to a second region of the base substrate.

3. The method of claim 2, wherein orthographic projections of the first mask and the second mask on the base substrate are overlapped at least partially with each other.

4. The method of claim 2, wherein orthographic projections of the first mask and the second mask on the base substrate are not overlapped with each other.

5. The method of claim 2, wherein the first mask and the second mask are at the same side of the base substrate.

6. The method of claim 2, wherein the first mask and the second mask are at different sides of the base substrate, respectively.

7. The method of claim 5, wherein at least one exposure light source is provided to be located at a side of the base substrate at which the first mask and the second mask are located.

8. The method of claim 6, wherein at least two exposure light sources are provided to be located at the different sides of the base substrate, respectively.

9. The method of claim 1, wherein a material for the film layer to be exposed is positive photoresist material, and the exposed pattern is complementary to a pattern obtained after overlapping all the masks of the mask combination with one another.

10. The method of claim 1, wherein a material for the film layer to be exposed is negative photoresist material, and the exposed pattern is a superimposed pattern obtained after overlapping all the masks of the mask combination with one another.

11. The method of claim 1, performed for manufacturing a black matrix layer or a color film layer.

12. A substrate comprising a base substrate and a black matrix layer and/or a color film layer on the base substrate; wherein,
the black matrix layer and/or the color film layer are/is formed by performing the exposure method of claim 1.

13. An exposure apparatus for manufacturing the substrate of claim 12, the exposure apparatus comprising: a first exposure machine and a second exposure machine provided to simultaneously perform exposures on the base substrate at different sides of the base substrate, respectively.

14. An exposure apparatus for manufacturing the substrate of claim 12, the exposure apparatus comprising: at least one exposure machine provided to perform exposures, by using different masks, on the base substrate at the same side of the base substrate.

15. The exposure apparatus of claim 13, wherein a material for the film layer to be exposed is positive photoresist material, and the exposed pattern is complementary to a pattern obtained after overlapping all the masks of the mask combination with one another.

16. The exposure apparatus of claim 13, wherein a material for the film layer to be exposed is negative photoresist material, and the exposed pattern is a superimposed pattern obtained after overlapping all the masks of the mask combination with one another.

17. The exposure apparatus of claim 13 which is configured for manufacturing a black matrix layer or a color film layer.

18. The exposure apparatus of claim 14, wherein a material for the film layer to be exposed is positive photoresist material, and the exposed pattern is complementary to a pattern obtained after overlapping all the masks of the mask combination with one another.

19. The exposure apparatus of claim 14, wherein a material for the film layer to be exposed is negative photoresist material, and the exposed pattern is a superimposed pattern obtained after overlapping all the masks of the mask combination with one another.

20. The exposure apparatus of claim 14 which is configured for manufacturing a black matrix layer or a color film layer.
